(19) United States
(12) Patent Application Publication
(10) Pub. No.: US 2026/0142080 A1
(43) Pub. Date: May 21, 2026

(54) FERROMAGNETIC CAPACITOR

(71) Applicants: NATIONAL INSTITUTE OF ADVANCED INDUSTRIAL SCIENCE AND TECHNOLOGY, Tokyo (JP); NATIONAL INSTITUTE FOR MATERIALS SCIENCE, Ibaraki (JP)

(72) Inventors: Takashi Onaya, Ibaraki (JP); Yukinori Morita, Ibaraki (JP); Hiroyuki Ota, Ibaraki (JP); Toshihide Nabatame, Ibaraki (JP)

(21) Appl. No.: 18/872,101

(22) PCT Filed: Apr. 21, 2023
(86) PCT No.: PCT/JP2023/016005

§ 371 Date: Dec. 5, 2024

(30) Foreign Application Priority Data
Jun. 8, 2022 (JP) 2022-092987

(51) Int. Cl. H01G 4/008; H01G 4/10; H01G 4/33

(52) U.S. Cl. CPC H01G 4/008; H01G 4/10; H01G 4/33

(57) ABSTRACT

Provided is a ferroelectric capacitor in which an increase in coercive electric field and degradation of rewrite resistance are suppressed with a simple structure. The ferroelectric capacitor of the present invention is a ferroelectric capacitor, including: an upper electrode; a lower electrode; and a ferroelectric layer arranged between the upper electrode and the lower electrode so as to be in close contact therewith, wherein at least one electrode selected from the group consisting of the upper electrode and the lower electrode includes a composite metal oxide electrode formed so as to contain a composite metal oxide in which a second oxide is added to a conductive first oxide containing at least one metal element selected from the group consisting of In, Ga, Zn, Sn, Ru, Ir and Sr at a molar ratio smaller than that of the first oxide, the second oxide having oxygen dissociation energy, when considered as a metal oxide of one of the metal elements, which is larger by 200 KJ/mol or more, as compared to the metal oxide having the largest oxygen dissociation energy among the first oxides.

### TECHNICAL FIELD

The present invention relates to a ferroelectric capacitor that exhibits excellent ferroelectric characteristics based on the selection of an electrode material.

### BACKGROUND ART

Along with the rapid development of cutting-edge technologies, such as AI and IoT, there is a demand for the early achievement of a high-performance semiconductor device that can process and store a huge amount of data.

After a HfO₂-based ferroelectric obtained by adding Si, Al, Zr or the like to HfO₂ was reported in 2011 as a key device satisfying the above-mentioned demand, a ferroelectric random access memory (FeRAM) formed of a one-transistor-one-capacitor (1T-1C) type, which is a non-volatile memory that can be operated at a high speed with low power consumption, has been attracting attention (see Non Patent Literature 1).

The above-mentioned HfO₂-based ferroelectric can be formed into a thin film (less than 10 nm), which is the limit reached by existing perovskite-based materials, such as Pb(Zr, Ti)O₃ (PZT) and SrBi₂Ta₂O₉ (SBT). The HfO₂-based ferroelectric is excellent in compatibility with a CMOS process and can also be homogeneously formed into a film on a three-dimensional structure along with the technological advance of an atomic layer deposition (ALD) method. Thus, an ultra-high-density and high performance ferroelectric non-volatile memory device, which has hitherto been difficult to achieve, is also expected to be achieved.

The ferroelectric phase of the HfO₂-based ferroelectric is considered to be a metastable and non-centrosymmetric orthorhombic phase (space group: Pca2₁) at normal temperature and normal pressure and exhibits polarization characteristics when oxygen atoms in a unit lattice move. Thus, it has been reported that the ferroelectricity of the HfO₂-based ferroelectric is greatly influenced by the transfer of oxygen atoms between adjacent interface materials and the formation of an interface layer (see Non Patent Literature 2).

In order to form the above-mentioned orthorhombic phase that is the ferroelectric phase of the HfO₂-based ferroelectric, a conductive material, such as a metal or a metal nitride (e.g., W or TiN), having a large difference in coefficient of thermal expansion as compared to the HfO₂-based ferroelectric has hitherto been used as an electrode material (see Patent Literature 1 and Non Patent Literatures 3 and 4).

However, it has been known that, when W or TiN is used as an electrode material, an interface layer is formed between the HfO₂-based ferroelectric and the electrode in a heat treatment step and oxygen moves from the HfO₂-based ferroelectric to the electrode side at the time of heat treatment due to the scavenging effect of TiN to form oxygen deficiency in a film of the HfO₂-based ferroelectric (see Non Patent Literature 5).

In addition, although an attempt has been made to form the HfO₂-based ferroelectric on Si for the purpose of application to a ferroelectric transistor, it has been known that a SiO₂ interface layer is easily formed at the interface between the layer of the HfO₂-based ferroelectric and the layer of Si (see Non Patent Literature 6).

As described above, a defect such as oxygen vacancy or an interface layer is easily formed between the electrode and the HfO₂-based ferroelectric in process steps, such as heat treatment and film formation and at the time of application of a voltage for rewriting or the like, and in association with the foregoing, an increase in coercive electric field and degradation of rewrite resistance, such as the occurrence of wake-up and polarization fatigue, have become problems (see Non Patent Literature 6).

In order to solve those problems, there has been proposed a ferroelectric capacitor in which an In—Ga—Zn—O-based oxide and an In—Ga—Zn—Sn—O-based oxide, which are amorphous metal oxides, are inserted between an upper electrode and the HfO₂-based ferroelectric (see Non Patent Literatures 7 and 8).

However, there is a problem in that sufficient effects are not obtained on the increase in coercive electric field and the degradation of rewrite resistance.

In addition, for the purposes of enabling a conductive electrode material except TiN to be used and achieving the reduction in heat treatment step, the improvement of performance of a ferroelectric material and the like, there has also been proposed a structure in which a ferroelectric layer is sandwiched between non-ferroelectric metal oxides (see Patent Literature 2).

In this proposal, a plurality of layers of two or more kinds of the non-ferroelectric metal oxides different from each other are laminated to form a composite laminate, and the composite laminate is arranged between the ferroelectric layer and a capacitor electrode. In addition, the material for forming each layer of the composite laminate is selected so that the conductivity of the entire composite laminate is lower than that of the capacitor electrode.

However, the composite laminate has problems in that it is difficult to produce the composite laminate because the production process thereof is complicated due to the multilayer structure and sufficient effects are not obtained on the increase in coercive electric field and the degradation of rewrite resistance.

### CITATION LIST

### Patent Literature

PTL 1: Patent JP 2015-015334 A

PTL 2: Patent JP 2021-073747 A

### Non Patent Literature

NPL 1: T. S. Boscke et al., Appl. Phys. Lett. 99, 102903 (2011).

NPL 2: M. Pesic et al., Adv. Funct. Mater. 26, 7486 (2016).

NPL 3: S. J. Kim et al., Appl. Phys. Lett. 111, 242901 (2017).

NPL 4: G. Karbasian et al., Appl. Phys. Lett. 111, 022907 (2017).

NPL 5: T. Ando, Materials 5, 478 (2012).

NPL 6: S. Oh et al., IEEE Electron Device Lett. 40(7), 1092 (2019).

NPL 7: F. Mo et al., Appl. Phys. Express 13, 074005 (2020).

NPL 8: J. Wu et al., VLSI Symposium on Technology, T16-2, June (2021).

### SUMMARY OF INVENTION

### Technical Problem

The present invention solves the above-mentioned various problems in the related art, and its object is to achieve the following. That is, the object of the present invention is to provide a ferroelectric capacitor in which an increase in coercive electric field and the degradation of rewrite resistance are suppressed with a simple structure.

### Solution to Problem

A solution to the above-mentioned problems is specifically as described below.
<1> A ferroelectric capacitor, including: an upper electrode; a lower electrode; and a ferroelectric layer arranged between the upper electrode and the lower electrode so as to be in close contact therewith, wherein at least one electrode selected from the group consisting of the upper electrode and the lower electrode includes a composite metal oxide electrode formed so as to contain a composite metal oxide in which a second oxide is added to a conductive first oxide containing at least one metal element selected from the group consisting of In, Ga, Zn, Sn, Ru, Ir and Sr at a molar ratio smaller than that of the first oxide, the second oxide having oxygen dissociation energy, when considered as a metal oxide of one of the metal elements, which is larger by 200 KJ/mol or more, as compared to the metal oxide having the largest oxygen dissociation energy among the first oxides.
<2> The ferroelectric capacitor according to the above-mentioned item <1>, wherein each of the upper electrode and the lower electrode includes the composite metal oxide electrode.
<3> The ferroelectric capacitor according to the above-mentioned item <1> or <2>, further including a contact electrode formed on a surface of a layer of the composite metal oxide electrode on an opposite side to a surface thereof in close contact with the ferroelectric layer.
<4> The ferroelectric capacitor according to any one of the above-mentioned items <1> to <3>, wherein the composite metal oxide is formed by adding 0.02 part by mole to 0.5 part by mole of the second oxide to 1 part by mole of the first oxide.
<5> The ferroelectric capacitor according to any one of the above-mentioned items <1> to <3>, wherein the composite metal oxide is formed by adding the second oxide containing at least one element selected from the group consisting of Zr, Ce, La, Si, Hf, Ta and C to the first oxide selected from the group consisting of a Sn—O-based oxide, an In—Sn—O-based oxide, a Ga—Sn—O-based oxide, a Zn—Sn—O-based oxide, an In—Ga—Sn—O-based oxide, an In—Zn—Sn—O-based oxide, a Ga—Zn—Sn—O-based oxide and an In—Ga—Zn—Sn—O-based oxide.
<6> The ferroelectric capacitor according to any one of the above-mentioned items <1> to <3>, wherein the composite metal oxide is formed by adding the second oxide containing at least one element selected from the group consisting of Er, Dy, Ni, V, Ge, Ti, W, Nb, Zr, Ce, La, Si, Hf, Ta and C to the first oxide selected from the group consisting of an In—O-based oxide, a Ga—O-based oxide, a Zn—O-based oxide, an In—Ga—O-based oxide, an In—Zn—O-based oxide, a Ga—Zn—O-based oxide and an In—Ga—Zn—O-based oxide.
<7> The ferroelectric capacitor according to the above-mentioned item <6>, wherein the composite metal oxide is formed by adding the second oxide containing at least one element selected from the group consisting of Ti, W, Nb, Zr, La, Si, Hf, Ta and C to the In—O-based oxide.
<8> The ferroelectric capacitor according to the above-mentioned item <7>, wherein the composite metal oxide contains an oxide selected from the group consisting of an In—W—O-based oxide and an In—Si—O-based oxide.
9> The ferroelectric capacitor according to any one of the above-mentioned items <1> to <3>, wherein the composite metal oxide is formed by adding the second oxide containing at least one element selected from the group consisting of Zr, Ce, La, Si, Hf, Ta and C to the first oxide selected from the group consisting of a Ru—O-based oxide, an Ir—O-based oxide, a Sr—Ru—O-based oxide and an In—Sr—Ru—O-based oxide.
<10> The ferroelectric capacitor according to the above-mentioned item <9>, wherein the composite metal oxide contains an In—Sr—Ru—Si—O-based oxide.
<11> The ferroelectric capacitor according to any one of the above-mentioned items <1> to <10>, wherein the composite metal oxide electrode has a thickness of from 0.5 nm to 20 nm.
<12> The ferroelectric capacitor according to any one of the above-mentioned items <3> to <11>, wherein the composite metal oxide electrode has a thickness of from 0.5 nm to 2 nm.

### Advantageous Effects of Invention

According to the present invention, the above-mentioned various problems in the related art can be solved, and the ferroelectric capacitor in which an increase in coercive electric field and the degradation of rewrite resistance are suppressed with a simple structure can be provided.

### BRIEF DESCRIPTION OF DRAWINGS

FIG. 1 is a sectional structural view of a ferroelectric capacitor according to a first embodiment of the present invention.

FIG. 2 is a diagram showing a list of oxygen dissociation energies of oxides.

FIG. 3 is a sectional structural view of a ferroelectric capacitor according to a second embodiment of the present invention.

FIG. 4 is a perspective view for illustrating one configuration of a ferroelectric capacitor according to Example.

FIG. 5 is a graph showing measurement results of polarization-electric field characteristics of respective ferroelectric capacitors according to Examples 1 and 2 and Comparative Example 1.

FIG. 6 is a graph showing measurement results of endurance characteristics (values each normalized with the maximum residual polarization value) of the respective ferroelectric capacitors according to Examples 1 and 2 and Comparative Example 1.

FIG. 7 is a perspective view for illustrating another configuration of a ferroelectric capacitor according to Example.

FIG. 8 is a perspective view for illustrating still another configuration of a ferroelectric capacitor according to Example.

FIG. 9 is a graph showing measurement results of endurance characteristics (values each normalized with the dielectric breakdown rewrite frequency of a sample including only a contact electrode without including a composite metal oxide electrode) of respective ferroelectric capacitors according to Examples 1, 2, 8 and 9 and Comparative Example 1.

### DESCRIPTION OF EMBODIMENTS

### First Embodiment

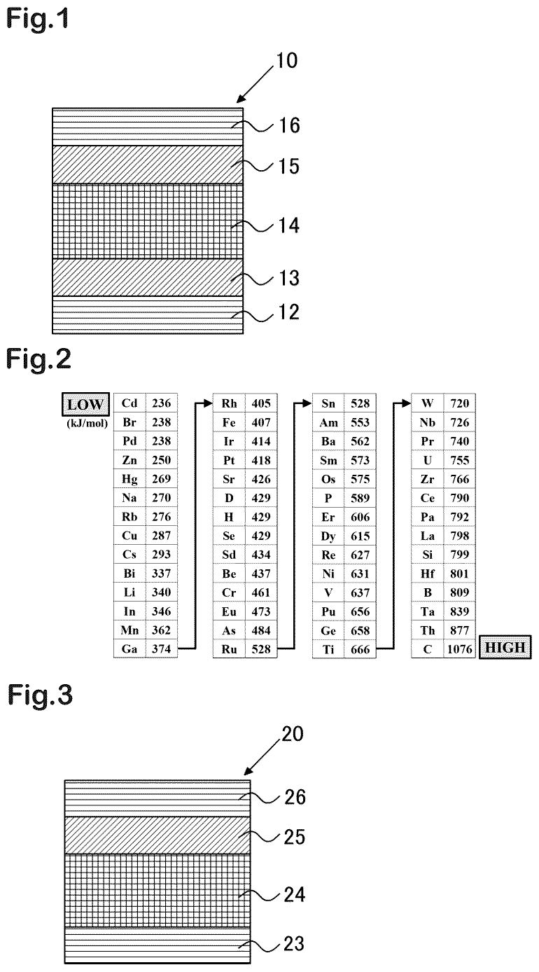

First, a ferroelectric capacitor according to a first embodiment of the present invention is described with reference to the drawings. FIG. 1 is a sectional structural view of the ferroelectric capacitor according to the first embodiment of the present invention.

As illustrated in FIG. 1, a ferroelectric capacitor 10 includes a lower contact electrode 12, a lower electrode 13, a ferroelectric layer 14, an upper electrode 15 and an upper contact electrode 16.

The lower electrode 13 and the upper electrode 15 are a pair of electrodes for applying a voltage to the ferroelectric layer 14.

Each of the lower electrode 13 and the upper electrode 15 in the first embodiment includes a composite metal oxide electrode described below.

The composite metal oxide electrode is an electrode formed so as to contain a composite metal oxide in which a second oxide is added to a first oxide.

The first oxide is a conductive oxide containing at least one metal element selected from the group consisting of In, Ga, Zn, Sn, Ru, Ir and Sr.

The first oxide is not particularly limited, and may be appropriately set in accordance with purposes. Specific examples thereof include known oxides suitably used as conductive metal oxides, such as an In—O-based oxide, a Ga—O-based oxide, a Zn—O-based oxide, a Sn—O-based oxide, an In—Ga—O-based oxide (IGO), an In—Zn—O-based oxide (IZO), an In—Sn—O-based oxide (ITO), a Ga—Zn—O-based oxide (GZO), a Ga—Sn—O-based oxide (GTO), a Zn—Sn—O-based oxide (ZTO), an In—Ga—Zn—O-based oxide (IGZO), an In—Ga—Sn—O-based oxide (IGTO), an In—Zn—Sn—O-based oxide (IZTO), a Ga—Zn—Sn—O-based oxide (GZTO), an In—Ga—Zn—Sn—O-based oxide (IGZTO), a Ru—O-based oxide, an Ir—O-based oxide and a Sr—Ru—O-based oxide. The examples also include various oxides (e.g., an In—Sr—Ru—O-based oxide, etc.) formed in conformity with known formation methods.

The term “conductive” as used herein means that an oxide has a resistivity of 1×10⁻⁴ Ω·m or less, and the term “-based oxide” as used herein means an oxide which contains all the elements described before this notation and in which the composition ratio of each element has all the ranges that can form the oxide in addition to stable composition.

Of the above-mentioned first oxides, an oxide containing In is preferred from the viewpoint of conductivity when considered as an electrode material.

In particular, although the oxide containing In is easily crystallized at low temperature at the time of film formation in the case of In₂O₃ alone, the addition of the second oxide can shift a crystallization start temperature to a high temperature side, and an amorphous structure is easily maintained. When the amorphous structure is maintained, surface roughness can be suppressed and leakage current can be reduced as compared to the crystallized case.

The second oxide is an oxide having oxygen dissociation energy, when considered as a metal oxide of one of the above-mentioned metal elements, which is larger by 200 kJ/mol or more, as compared to the metal oxide having the largest oxygen dissociation energy among the first oxides.

When the second oxide having the large oxygen dissociation energy is added, the formation of defects, such as an interface layer and oxygen deficiency, at the interface between the electrode and the ferroelectric layer, causing an increase in coercive electric field, which has hitherto occurred in the related-art ferroelectric capacitor, can be suppressed, and the formation of defects such as new oxygen deficiency caused by movement of oxygen atoms during an operation through application of a voltage can also be suppressed.

Such suppressing effect on the formation of defects may be imparted by the second oxide having the oxygen dissociation energy larger than that of the first oxide. When the difference in oxygen dissociation energy between the first oxide and the second oxide is larger, the above-mentioned effect is significantly exhibited, and hence the composite metal oxide electrode is formed by providing a sufficient difference.

The second oxide is added to the conductive first oxide at a molar ratio smaller than that of the first oxide.

That is, in the composite metal oxide electrode formed so as to contain the first oxide and the second oxide, the conductivity of the first oxide exhibits a dominant property, and the conductivity is imparted to the composite metal oxide electrode.

In particular, when the composite metal oxide is formed by adding the second oxide at a ratio of 0.5 part by mole or less with respect to 1 part by mole of the first oxide, suitable conductivity is obtained.

Meanwhile, when the composite metal oxide is formed by adding the second oxide at a ratio of less than 0.02 part by mole with respect to 1 part by mole of the first oxide, the formation of defects such as oxygen deficiency may not be effectively suppressed.

Accordingly, the composite metal oxide is particularly preferably formed by adding 0.02 part by mole to 0.5 part by mole of the second oxide to 1 part by mole of the first oxide.

The second oxide is more specifically described with reference to FIG. 2. FIG. 2 is a diagram showing a list of oxygen dissociation energies of oxides.

Elements shown in FIG. 2 are each listed in such a manner that the oxygen dissociation energy when the element is considered as an oxide is increased from Cd (236 KJ/mol) in the upper left to C (1,076 KJ/mol) in the lower right in the figure, and the number on the right side of each of the elements indicates the magnitude (kJ/mol) of the oxygen dissociation energy. The selection of the second oxide with respect to the first oxide may be made with reference to FIG. 2.

For example, when an In oxide that is a unitary oxide is selected as the first oxide, an Am oxide (553 KJ/mol) or subsequent oxides each having the oxygen dissociation energy larger than the oxygen dissociation energy of the In oxide (346 KJ/mol) by 200 KJ/mol or more may be selected as the second oxide in accordance with FIG. 2.

In addition, when an In—Ga—Zn—O-based oxide that is a ternary oxide is selected as the first oxide, the oxygen dissociation energy when considered as each of metal oxides (In oxide, Ga oxide and Zn oxide) of one of the metal elements (single metal elements: In, Ga and Zn) is found in accordance with FIG. 2, and an Os oxide (575 KJ/mol) or subsequent oxides each having the oxygen dissociation energy larger than that of the Ga oxide (374 KJ/mol), which is the metal oxide having the largest oxygen dissociation energy among those metal oxides, by 200 KJ/mol or more may be selected.

The details of the oxygen dissociation energies of the oxides may be found with reference to Reference 1 below.

Reference 1: Y.-R. Luo, Comprehensive Handbook of Chemical Bond Energies, CRC Press (2007).

The second oxide may be selected as described above with respect to the first oxide, but in particular, from the viewpoint of the conductivity of the composite metal oxide electrode to be obtained, the following oxides are preferred.

That is, when the first oxide is selected from the group consisting of a Sn—O-based oxide, an In—Sn—O-based oxide, a Ga—Sn—O-based oxide, a Zn—Sn—O-based oxide, an In—Ga—Sn—O-based oxide, an In—Zn—Sn—O-based oxide, a Ga—Zn—Sn—O-based oxide and an In—Ga—Zn—Sn—O-based oxide, the second oxide is preferably an oxide containing at least one element selected from the group consisting of Zr, Ce, La, Si, Hf, Ta and C.

In addition, when the first oxide is selected from the group consisting of an In—O-based oxide, a Ga—O-based oxide, a Zn—O-based oxide, an In—Ga—O-based oxide, an In—Zn—O-based oxide, a Ga—Zn—O-based oxide and an In—Ga—Zn—O-based oxide, the second oxide is preferably an oxide containing at least one element selected from the group consisting of Er, Dy, Ni, V, Ge, Ti, W, Nb, Zr, Ce, La, Si, Hf, Ta and C. From the viewpoints of ease of handling and ease of availability of a material, it is particularly preferred that an In—O-based oxide out of those oxides be selected as the first oxide, and an oxide containing at least one element selected from the group consisting of Ti, W, Nb, Zr, La, Si, Hf, Ta and C out of those oxides be selected as the second oxide.

In addition, when the first oxide is selected from the group consisting of a Ru—O-based oxide, an Ir—O-based oxide, a Sr—Ru—O-based oxide and an In—Sr—Ru—O-based oxide, the second oxide is preferably an oxide containing at least one element selected from the group consisting of Zr, Ce, La, Si, Hf, Ta and C.

In addition, as described above, the composite metal oxide may have various material configurations depending on the selection of the first oxide and the second oxide, but in particular, the composite metal oxide preferably contains at least one of an In—W—O-based oxide and an In—Si—O-based oxide or preferably contains an In—Sr—Ru—Si—O-based oxide based on the reasons described for the selection of the first oxide and the second oxide.

When both the lower electrode 13 and the upper electrode 15 are each formed of the composite metal oxide electrode, the composite metal oxide electrode for forming the lower electrode 13 and the composite metal oxide electrode for forming the upper electrode 15 may be formed of the same kind of composite metal oxide or may be formed of different kinds of composite metal oxides.

In addition, the composite metal oxide may be in a crystalline state but preferably has an amorphous structure from the viewpoint of enhancing performance at the time of device configuration. The amorphous structure can suppress surface roughness and reduce leakage current as compared to the crystalized case.

The thickness of the layer of the composite metal oxide electrode is not particularly limited and may be appropriately selected in accordance with purposes. However, from the viewpoints that the layer can be formed as a monomolecular film and that a low resistance value at which the layer can function as an electrode is obtained, the thickness is preferably at least 0.5 nm or more. In addition, from the viewpoint of increasing a density at the time of device configuration, the thickness is preferably at most 100 nm or less. The thickness is particularly preferably from 0.5 nm to 20 nm out of the thicknesses from the above-mentioned viewpoints.

In addition, when the contact electrodes (the lower contact electrode 12 and the upper contact electrode 16) are arranged in parallel to the composite metal oxide electrode, the composite metal oxide electrode may be further reduced in thickness, and the thickness of the layer of the composite metal oxide electrode in this case is particularly preferably from 0.5 nm to 2 nm.

The direction of the “thickness” as used herein means the up-and-down direction as described in the notation for the lower electrode 13 and the upper electrode 15.

A method of forming the composite metal oxide is not particularly limited and may be appropriately selected in accordance with purposes, and an example thereof is a known DC sputtering method using the first oxide and the second oxide as target materials.

The description “the composite metal oxide is formed by adding the second oxide to the first oxide” does not specify the method of forming the composite metal oxide but means that a component of the first oxide and a component of the second oxide are contained in the composition of the composite metal oxide to be finally formed.

For example, of several methods of forming an In—Sr—Ru—Si—O-based oxide serving as the composite metal oxide, one formation method involves forming an In—Sr—Ru—Si—O-based oxide by a co-sputtering method using the following two target materials: a target material of SrRuOs that may form the first oxide; and a target material of an In—Si—O-based oxide containing a SiO₂ component that is the second oxide and an In₂O₃ component that may form the first oxide in its composition. The In—Sr—Ru—Si—O-based oxide corresponds to the composite metal oxide, which contains a component of an In—Sr—Ru—O-based oxide serving as the first oxide and a component of SiO₂ serving as the second oxide in its composition, and which is formed by adding the second oxide to the first oxide.

Referring again to FIG. 1, the ferroelectric layer 14 is arranged between the upper electrode 15 and the lower electrode 13 so as to be in close contact therewith.

A formation material for the ferroelectric layer 14 is not particularly limited and may be appropriately selected from ferroelectric materials formed of known oxides in accordance with purposes.

That is, from the viewpoint of obtaining a high-performance device, preferred examples of the material may include high-performance ferroelectric materials, such as a hafnium-based oxide (oxide obtained by doping HfO₂ with different kinds of elements, such as Si, Al and Zr), a hafnium oxide (HfO₂), a zirconium oxide (ZrO₂) and a zirconium-hafnium oxide (HfₓZr₁₋ₓO₂, where “x” represents a numerical value of 0 or more and less than 1). However, even when a ferroelectric material formed of an oxide of a perovskite-based material, such as Pb(Zr, Ti)O₃ (PZT) or SrBi₂TaO₉ (SBT), is selected, the suppressing effect on the formation of defects such as oxygen deficiency caused by the second oxide having the large oxygen dissociation energy is obtained.

In addition, the ferroelectric layer 14 may be formed of a composite laminate structure of such ferroelectric metal oxide and a non-ferroelectric metal oxide, such as AlOₓ or TiOₓ. The composite laminate structure may be appropriately selected from known structures.

The thickness of the ferroelectric layer 14 is not particularly limited and also depends on a formation material. However, from the viewpoint of increasing a density at the time of device configuration, the thickness is preferably small. When the high-performance ferroelectric material is selected, the thickness is preferably from about 0.5 nm to about 100 nm. When the perovskite-based material is selected, the thickness is preferably from about 10 nm to about 100 nm based on the limit of reducing the thickness.

A method of forming the ferroelectric layer 14 is not particularly limited and may be appropriately selected in accordance with purposes, and an example thereof is a known atomic layer deposition method (ALD method).

The lower contact electrode 12 and the upper contact electrode 16 are arranged in order to assist the electrode actions of the lower electrode 13 and the upper electrode 15.

That is, with respect to the layered lower electrode 13 and upper electrode 15 (each of which is formed of the composite metal oxide electrode), those contact electrodes are formed on surfaces of the lower electrode 13 and the upper electrode 15 on an opposite side to surfaces thereof in close contact with the ferroelectric layer 14 and assist the electrode actions of the lower electrode 13 and upper electrode 15.

A formation material for each of the lower contact electrode 12 and the upper contact electrode 16 preferably has a resistivity lower than that of the composite metal oxide and may be appropriately selected from known metal materials (e.g., Au and Ti), metal oxides (e.g., RuOₓ and IrOₓ), metal nitrides (e.g., TiN) and the like. In addition, the lower contact electrode 12 and the upper contact electrode 16 may each be formed as a laminate structure of materials each having a resistivity lower than that of the composite metal oxide. The lower contact electrode 12 and the upper contact electrode 16 may each be formed by a known method in accordance with selected materials. In addition, the thickness of the lower contact electrode 12 and the upper contact electrodes 16 is preferably from about 2 nm to about 100 nm.

When the conductivity of each of the lower electrode 13 and the upper electrode 15 is sufficiently high for the purpose of an applicable device, the lower contact electrode 12 and the upper contact electrode 16 are not required.

Thus, the lower contact electrode 12 and the upper contact electrode 16 are optional constituent members, and there is also provided a modification example obtained by removing the lower contact electrode 12 and the upper contact electrode 16 from the ferroelectric capacitor 10.

### Second Embodiment

Next, a ferroelectric capacitor according to a second embodiment of the present invention is described with reference to FIG. 3. FIG. 3 is a sectional structural view of the ferroelectric capacitor according to the second embodiment of the present invention.

As illustrated in FIG. 3, a ferroelectric capacitor 20 includes a lower electrode 23, a ferroelectric layer 24, an upper electrode 25 and an upper contact electrode 26.

The ferroelectric layer 24, the upper electrode 25 and the upper contact electrode 26 are configured in the same manner as in the ferroelectric layer 14, the upper electrode 15 and the upper contact electrode 16 in the ferroelectric capacitor 10.

In addition, the lower electrode 23 is configured in the same manner as in the lower contact electrode 12 in the ferroelectric capacitor 10.

That is, in the ferroelectric capacitor 20, of the pair of lower electrode 23 and the upper electrode 25, only the upper electrode 25 is formed of the composite metal oxide electrode.

Even in such ferroelectric capacitor 20, the suppressing effect on the formation of defects such as oxygen deficiency caused by the second oxide having the large oxygen dissociation energy contained in the composite metal oxide electrode is obtained on an upper surface side of the ferroelectric layer 24.

The upper contact electrode 26 is an optional constituent member, and there is also provided a modification example obtained by removing the upper contact electrode 26 from the ferroelectric capacitor 20.

### EXAMPLES

### Example 1; Composite Metal Oxide Electrode in Which WO₃ is Added to In₂O₃

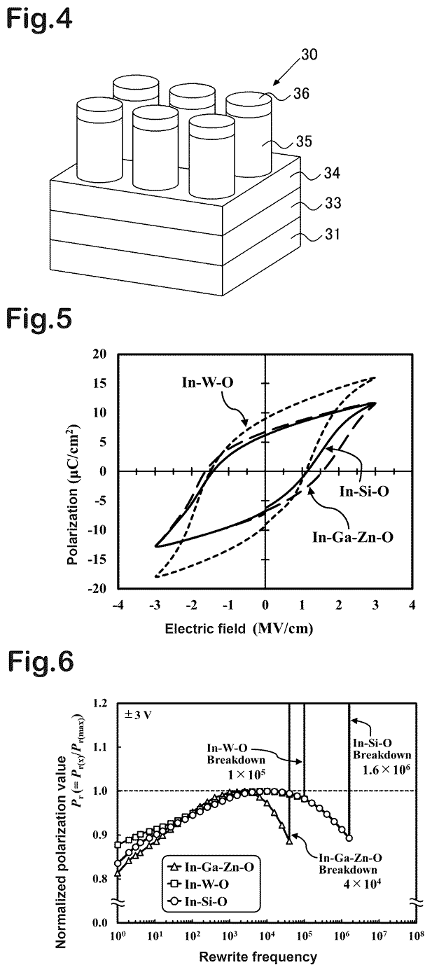

In order to verify the effects of the present invention, a ferroelectric capacitor according to Example was produced in a configuration illustrated in FIG. 4. FIG. 4 is a perspective view for illustrating one configuration of the ferroelectric capacitor according to Example.

The ferroelectric capacitor according to Example 1 was produced as described below.

First, a TiN layer serving as a lower electrode 33 was formed into a film having a thickness of 15 nm on a p-type Si substrate 31 treated with buffered hydrofluoric acid (BHF) by a DC sputtering method.

Next, a HfₓZr₁₋ₓO₂ (HZO) (Hf/Zr=0.43:0.57) layer serving as a ferroelectric layer 34 was formed into a film having a thickness of 10 nm on the lower electrode 33 by an atomic layer deposition (ALD) method.

Next, an upper electrode 35 serving as a composite metal oxide electrode was formed on the ferroelectric layer 34.

Here, the upper electrode 35 was formed of an In—W—O-based oxide (IWO) in which WO₃ (720 KJ/mol) having oxygen dissociation energy larger than that of In₂O₃ (346 KJ/mol) by 200 KJ/mol or more was added to In₂O₃, and the upper electrode 35 was formed into a film having a thickness of 10 nm by a DC sputtering method (DC power: 200 W, process gas flow rate: Ar 6 sccm/O₂ 6 sccm, substrate temperature: room temperature (23° C.)) as an In—W—O-based oxide electrode containing In₂O₃ and WO₃ at a ratio of 0.11 mol % of WO₃ per 1 mol % of In₂O₃(In₂O₃:WO₃=1 mol %:0.11 mol %) by adjusting the composition of target materials.

Next, rapid heating treatment was performed at 400° C. for 1 minute in the air.

Next, a laminated electrode of a Ti layer (thickness: 10 nm) and an Au layer (thickness: 100 nm) serving as a contact electrode 36 was formed on the upper electrode 35 by a resistance heating vapor deposition method.

The upper electrode 35 and the contact electrode 36 were formed as a laminate having a columnar shape as a whole through use of a stencil mask. Thus, a ferroelectric capacitor 30 was produced as the ferroelectric capacitor according to Example 1.

### Example 2; Composite Metal Oxide Electrode in Which SiO₂ is Added to In₂O₃

A ferroelectric capacitor according to Example 2 was produced in the same manner as in Example 1 except that: the upper electrode 35 was formed of an In—Si—O-based oxide (ISO) in which SiO₂ (799 KJ/mol) having oxygen dissociation energy larger than that of In₂O₃ (346 KJ/mol) by 200 KJ/mol or more was added to In₂O₃; and the upper electrode 35 was formed into a film having a thickness of 10 nm by the DC sputtering method (DC power: 200 W, process gas flow rate: Ar 6 sccm/O₂ 6 sccm, substrate temperature: room temperature (23° C.)) as an In—Si—O-based oxide electrode containing In₂O₃ and SiO₂ at a ratio of 0.26 mol % of SiO₂ per 1 mol % of In₂O₃(In₂O₃:SiO₂=1 mol %:0.26 mol %) by adjusting the composition of target materials.

### Comparative Example 1; Electrode in which Ga₂O₃ and ZnO are Added to In₂O₃ (IGZO Electrode)

A ferroelectric capacitor according to Comparative Example 1 was produced in the same manner as in Example 1 except that: the upper electrode 35 was formed of an In—Ga—Zn—O-based oxide (IGZO); and the upper electrode 35 was formed into a film having a thickness of 10 nm by the DC sputtering method (DC power: 100 W, process gas flow rate: Ar 21.2 sccm/O₂ 1.5 sccm, substrate temperature: room temperature (23° C.)) as an In—Ga—Zn—O-based oxide electrode containing In₂O₃, Ga₂O₃ and ZnO in equimolar amounts by adjusting the composition of target materials.

FIG. 5 shows measurement results of polarization-electric field characteristics of each of the ferroelectric capacitors according to Examples 1 and 2 and Comparative Example 1.

As shown in FIG. 5, a clear hysteresis loop caused by ferroelectricity is recognized in each of the ferroelectric capacitors according to Examples 1 and 2 and Comparative Example 1.

Meanwhile, the coercive electric field of the ferroelectric capacitor according to Example 1 (using the In—W—O-based oxide electrode) was 1.30 MV/cm, and the coercive electric field of the ferroelectric capacitor according to Example 2 (using the In—Si—O-based oxide electrode) was 1.29 MV/cm. Those ferroelectric capacitors exhibited the values smaller than the coercive electric field of 1.59 MV/cm of the ferroelectric capacitor according to Comparative Example 1 using the In—Ga—Zn—O-based oxide electrode in which Ga₂O₃ and ZnO each having oxygen dissociation energy equal to or less than that of In₂O₃ were added to In₂O₃.

The reason for the foregoing is conceived as described below. The upper electrode 35 included the composite metal oxide electrode having the large oxygen dissociation energy, and as a result, the formation of defects, such as an interface layer and oxygen deficiency, at the interface between the upper electrode 35 and the ferroelectric layer 34, causing an increase in coercive electric field, was able to be suppressed.

FIG. 6 shows measurement results of endurance characteristics (values normalized with the maximum residual polarization value) of each of the ferroelectric capacitors according to Examples 1 and 2 and Comparative Example 1.

As shown in FIG. 6, the ferroelectric capacitor according to Example 1 (using the In—W—O-based oxide electrode) and the ferroelectric capacitor according to Example 2 (using the In—Si—O-based oxide electrode) exhibited smaller wake-up and polarization fatigue characteristics as compared to the ferroelectric capacitor according to Comparative Example 1 using the In—Ga—Zn—O-based oxide electrode in which Ga₂O₃ and ZnO each having oxygen dissociation energy equal to or less than that of In₂O₃ were added to In₂O₃.

In addition, as shown in FIG. 6, a rewritable frequency was increased along with an increase in oxygen dissociation energy of the oxide added to In₂O₃. In the ferroelectric capacitor according to Comparative Example 1 (using the In—Ga—Zn—O-based oxide electrode), the rewritable frequency became 4.0×10⁴ times. In the ferroelectric capacitor according to Example 1 (using the In—W—O-based oxide electrode), the rewritable frequency became 1.0×10⁵ times. In the ferroelectric capacitor according to Example 2 (using the In—Si—O-based oxide electrode), the rewritable frequency was 1.6×10⁶ times.

The results shown in FIG. 6 support the discussion that, when the upper electrode 35 included the composite metal oxide electrode having the large oxygen dissociation energy, the formation of defects such as oxygen deficiency caused by movement of oxygen atoms during an operation through application of a voltage, as well as unintended defects, such as an interface layer and oxygen deficiency, formed in a production process can be suppressed, and it is conceived that such suppression effect is exhibited depending on the magnitude of the oxygen dissociation energy.

### Example 3; Composite Metal Oxide Electrode in Which SiO₂ is Added to In—Sn—O-Based Oxide

A ferroelectric capacitor according to Example 3 was produced in the same manner as in Example 1 except that: the upper electrode 35 was formed of an In—Sn—Si—O-based oxide in which SiO₂ (799 KJ/mol) having oxygen dissociation energy larger than that of SnO₂ (528 KJ/mol) by 200 KJ/mol or more was added to an In—Sn—O-based oxide (ITO); and in a co-sputtering method using In—Sn—O and SiO₂ targets containing SnO₂ at a ratio of 0.20 mol % per 1 mol % of In₂O₃, sputtering using the In—Sn—O target was performed by a DC system, sputtering using the SiO₂ target was performed by a RF system, an In—Sn—Si—O-based oxide electrode containing In₂O₃, SnO₂ and SiO₂ at a ratio of 0.24 mol % of SiO₂ per 1 mol % of In₂O₃(In₂O₃:SnO₂:SiO₂=1 mol %:0.20 mol %:0.24 mol %) was formed into a film having a thickness of 10 nm by changing the ratio of each sputtering power, and the In—Sn—Si—O-based oxide electrode was used as the upper electrode 35.

### Example 4; Composite Metal Oxide Electrode in Which SiO₂ is Added to SnO₂

A ferroelectric capacitor according to Example 4 was produced in the same manner as in Example 1 except that: the upper electrode 35 was formed of a Sn—Si—O-based oxide in which SiO₂ (799 KJ/mol) having oxygen dissociation energy larger than that of SnO₂ (528 KJ/mol) by 200 KJ/mol or more was added to SnO₂; and in a co-sputtering method using SnO₂ and SiO₂ targets, sputtering using the SnO₂ target was performed by a DC system, sputtering using the SiO₂ target was performed by a RF system, a Sn—Si—O-based oxide electrode containing SnO₂ and SiO2 at a ratio of 0.20 mol % of SiO₂ per 1 mol % of SnO₂ (SnO₂:SiO₂=1 mol %:0.20 mol %) was formed into a film having a thickness of 10 nm by changing the ratio of each sputtering power, and the Sn—Si—O-based oxide electrode was used as the upper electrode 35.

### Example 5; Composite Metal Oxide Electrode in Which WO₃ is Added to In—Ga—Zn—O-Based Oxide

A ferroelectric capacitor according to Example 5 was produced in the same manner as in Example 1 except that: the upper electrode 35 was formed of an In—Ga—Zn—W—O-based oxide in which WO₃ (720 KJ/mol) having oxygen dissociation energy larger than that of GaO (374 KJ/mol) by 200 KJ/mol or more was added to an In—Ga—Zn—O-based oxide (IGZO); and in a co-sputtering method using In—Ga—Zn—O and WO₃ targets containing In₂O₃, Ga₂O₃ and ZnO in equimolar amounts, sputtering using the In—Ga—Zn—O target was performed by a DC system, sputtering using the WO₃ target was performed by a RF system, an In—Ga—Zn—W—O-based oxide electrode containing In₂O₃, Ga₂O₃, ZnO and WO₃ at a ratio of 0.24 mol % of WO₃ per 1 mol % of each of In₂O₃, Ga₂O₃ and ZnO (In₂O₃:Ga₂O₃:ZnO:WO₃=1 mol %:1 mol %:1 mol %:0.24 mol %) was formed into a film having a thickness of 10 nm by changing the ratio of each sputtering power, and the In—Ga—Zn—W—O-based oxide electrode was used as the upper electrode 35.

### Example 6; Composite Metal Oxide Electrode in Which SiO₂ is Added to Ga₂O₃

A ferroelectric capacitor according to Example 6 was produced in the same manner as in Example 1 except that: the upper electrode 35 was formed of a Ga—Si—O-based oxide in which SiO₂ (799 KJ/mol) having oxygen dissociation energy larger than that of Ga₂O₃ (374 KJ/mol) by 200 KJ/mol or more was added to Ga₂O₃; and in a co-sputtering method using Ga₂O₃ and SiO₂ targets, sputtering using the Ga₂O₃ target was performed by a DC system, sputtering using the SiO₂ target was performed by a RF system, a Ga—Si—O-based oxide electrode containing Ga₂O₃ and SiO₂ at a ratio of 0.11 mol % of SiO₂ per 1 mol % of Ga₂O₃(Ga₂O₃:SiO₂=1 mol %:0.11 mol %) was formed into a film having a thickness of 10 nm by changing the ratio of each sputtering power, and the Ga—Si—O-based oxide electrode was used as the upper electrode 35.

### Example 7; Composite Metal Oxide Electrode in Which SiO₂ is Added to ZnO

A ferroelectric capacitor according to Example 7 was produced in the same manner as in Example 1 except that: the upper electrode 35 was formed of a Zn—Si—O-based oxide in which SiO₂ (799 KJ/mol) having oxygen dissociation energy larger than that of ZnO (250 KJ/mol) by 200 KJ/mol or more was added to ZnO; and in a co-sputtering method using ZnO and SiO₂ targets, sputtering using the ZnO target was performed by a DC system, sputtering using the SiO₂ target was performed by a RF system, a Zn—Si—O-based oxide electrode containing ZnO and SiO₂ at a ratio of 0.12 mol % of SiO₂ per 1 mol % of ZnO (ZnO:SiO₂=1 mol %:0.12 mol %) was formed into a film having a thickness of 10 nm by changing the ratio of each sputtering power, and the Zn—Si—O-based oxide electrode was used as the upper electrode 35.

### Example 8; Composite Metal Oxide Electrode in Which SiO₂ is Added to RuO₂

A ferroelectric capacitor according to Example 8 was produced in the same manner as in Example 1 except that: the upper electrode 35 was formed of a Ru—Si—O-based oxide in which SiO₂ (799 KJ/mol) having oxygen dissociation energy larger than that of RuO₂ (528 KJ/mol) by 200 KJ/mol or more was added to RuO₂; and in a co-sputtering method of a RF system using RuO₂ and SiO₂ targets, a Ru—Si—O-based oxide electrode containing RuO₂ and SiO₂ at a ratio of 0.28 mol % of SiO₂ per 1 mol % of RuO₂ (RuO₂:SiO₂=1 mol %:0.28 mol %) was formed into a film having a thickness of 10 nm by changing the ratio of each sputtering power, and the Ru—Si—O-based oxide electrode was used as the upper electrode 35.

### Example 9; Composite Metal Oxide Electrode in Which SiO₂ is Added to IrO₂

A ferroelectric capacitor according to Example 9 was produced in the same manner as in Example 1 except that: the upper electrode 35 was formed of an Ir—Si—O-based oxide in which SiO₂ (799 KJ/mol) having oxygen dissociation energy larger than that of IrO₂ (414 KJ/mol) by 200 KJ/mol or more was added to IrO₂; and in a co-sputtering method of a RF system using IrO₂ and SiO₂ targets, an Ir—Si—O-based oxide electrode containing IrO₂ and SiO₂ at a ratio of 0.23 mol % of SiO₂ per 1 mol % of IrO₂ (IrO₂:SiO₂=1 mol %:0.23 mol %) was formed into a film having a thickness of 10 nm by changing the ratio of each sputtering power, and the Ir—Si—O-based oxide electrode was used as the upper electrode 35.

### Example 10; Composite Metal Oxide Electrode in Which SiO₂ is Added to SrRuO₃

A ferroelectric capacitor according to Example 10 was produced in the same manner as in Example 1 except that: the upper electrode 35 was formed of a Sr—Ru—Si—O-based oxide in which SiO₂ (799 KJ/mol) having oxygen dissociation energy larger than that of RuO₂ (528 KJ/mol) by 200 KJ/mol or more was added to SrRuO₃; and in a co-sputtering method of a RF system using SrRuO₃ and SiO₂ targets, a Sr—Ru—Si—O-based oxide electrode containing SrRuO₃ and SiO₂ at a ratio of 0.16 mol % of SiO₂ per 1 mol % of SrRuO₃ (SrRuO₃:SiO₂=1 mol %:0.16 mol %) was formed into a film having a thickness of 10 nm by changing the ratio of each sputtering power, and the Sr—Ru—Si—O-based oxide electrode was used as the upper electrode 35.

### Example 11; Composite Metal Oxide Electrode in Which In—Si—O-Based Oxide is Added to SrRuO₃

A ferroelectric capacitor according to Example 11 was produced in the same manner as in Example 1 except that: the upper electrode 35 was formed of an In—Sr—Ru—Si—O-based oxide containing an In—Si—O-based oxide in which SiO₂ (799 KJ/mol) having oxygen dissociation energy larger than that of RuO₂ (528 KJ/mol) by 200 KJ/mol or more was added to SrRuO₃; and in a co-sputtering method using a SrRuO₃ target and an In—Si—O-based oxide target containing In₂O₃ and SiO₂ at a ratio of 0.26 mol % of SiO₂ per 1 mol % of In₂O₃ (In₂O₃:SiO₂=1 mol %:0.26 mol %) by adjusting the composition, sputtering using the SrRuO₃ target was performed by a RF system, sputtering using the In—Si—O-based oxide target was performed by a DC system, an In—Sr—Ru—Si—O-based oxide electrode containing SrRuO₃, In₂O₃ and SiO₂ at a ratio of 0.88 mol % of In₂O₃ and 0.23 mol % of SiO₂ per 1 mol % of SrRuO₃ (SrRuO₃:In₂O₃:SiO₂=1 mol %:0.88 mol %:0.23 mol %) was formed into a film having a thickness of 10 nm by changing the ratio of each sputtering power, and the In—Sr—Ru—Si—O-based oxide electrode was used as the upper electrode 35.

In each of the ferroelectric capacitors according to Examples 3 to 11, ferroelectricity and endurance characteristics more satisfactory than those of the ferroelectric capacitor according to Comparative Example 1 were obtained in the same manner as in each of the ferroelectric capacitors according to Examples 1 and 2.

Those results mean that, even when the constituent materials of the composite metal oxide electrode are changed, the ferroelectric capacitor having excellent ferroelectricity and endurance characteristics is obtained as long as the second oxide having the large oxygen dissociation energy is added to the first oxide.

### Example 12: Composite Metal Oxide Electrode Applied to Lower Electrode

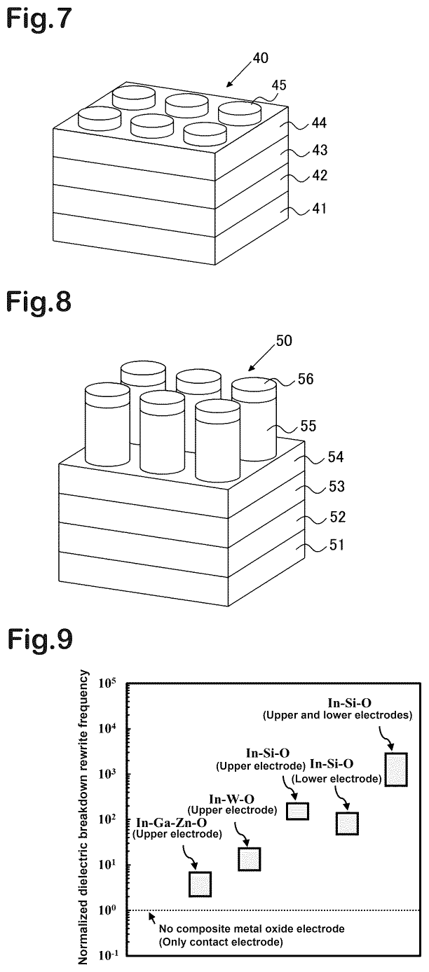

In addition, a ferroelectric capacitor according to another Example was produced in a configuration illustrated in FIG. 7. FIG. 7 is a perspective view for illustrating another configuration of the ferroelectric capacitor according to Example. In a ferroelectric capacitor 40 illustrated in FIG. 7, unlike the ferroelectric capacitor 30 illustrated in FIG. 4, a lower electrode 43 includes the composite metal oxide electrode, and an electrode on an upper side includes only an upper electrode 45 that is formed in the same manner as in the upper contact electrode 36.

A ferroelectric capacitor according to Example 12 was produced as described below.

First, a TiN layer serving as a contact electrode 42 was formed into a film having a thickness of 15 nm on a p-type Si substrate 41 treated with buffered hydrofluoric acid (BHF) by a DC sputtering method.

Next, the lower electrode 43 serving as a composite metal oxide electrode was formed on the contact electrode 42.

Here, the lower electrode 43 was formed of an In—Si—O-based oxide (ISO) in which SiO₂ (799 KJ/mol) having oxygen dissociation energy larger than that of In₂O₃ (346 KJ/mol) by 200 KJ/mol or more was added to In₂O₃, and the lower electrode 43 was formed into a film having a thickness of 10 nm by a DC sputtering method (DC power: 200 W, process gas flow rate: Ar 6 sccm/O₂ 6 sccm, substrate temperature: room temperature (23° C.)) as an In—Si—O-based oxide electrode containing In₂O₃ and SiO₂ at a ratio of 0.26 mol % of SiO₂ per 1 mol % of In₂O₃(In₂O₃:SiO₂=1 mol %:0.26 mol %) by adjusting the composition of target materials.

Next, a HfₓZr₁₋ₓO₂ (HZO) (Hf/Zr=0.43:0.57) layer serving as a ferroelectric layer 44 was formed into a film having a thickness of 10 nm on the lower electrode 43 by an atomic layer deposition (ALD) method.

Next, rapid heating treatment was performed at 400° C. for 1 minute in the air.

Next, a laminated electrode of a Ti layer (thickness: 10 nm) and a Au layer (thickness: 100 nm) serving as the upper electrode 45 was formed on the ferroelectric layer 44 by a resistance heating vapor deposition method.

Thus, the ferroelectric capacitor 40 was produced as the ferroelectric capacitor according to Example 12.

### Example 13: Composite Metal Oxide Electrode Applied to both Electrodes of Upper Electrode and Lower Electrode

In addition, a ferroelectric capacitor according to still another Example was produced in a configuration illustrated in FIG. 8. FIG. 8 is a perspective view for illustrating still another configuration of the ferroelectric capacitor according to Example. In a ferroelectric capacitor 50 illustrated in FIG. 8, unlike the ferroelectric capacitors 30 and 40 illustrated in FIG. 4 and FIG. 7, both electrodes of an upper electrode 55 and a lower electrode 53 each include the composite metal oxide electrode.

A ferroelectric capacitor according to Example 13 was produced as described below.

First, a TiN layer serving as a contact electrode 52 was formed into a film having a thickness of 15 nm on a p-type Si substrate 51 treated with buffered hydrofluoric acid (BHF) by a DC sputtering method.

Next, the lower electrode 53 serving as a composite metal oxide electrode was formed on the contact electrode 52.

Here, the lower electrode 53 was formed of an In—Si—O-based oxide (ISO) in which SiO₂ (799 KJ/mol) having oxygen dissociation energy larger than that of In₂O₃ (346 KJ/mol) by 200 KJ/mol or more was added to In₂O₃, and the lower electrode 53 was formed into a film having a thickness of 10 nm by a DC sputtering method (DC power: 200 W, process gas flow rate: Ar 6 sccm/O₂ 6 sccm, substrate temperature: room temperature (23° C.)) as an In—Si—O-based oxide electrode containing In₂O₃ and SiO₂ at a ratio of 0.26 mol % of SiO₂ per 1 mol % of In₂O₃(In₂O₃:SiO₂=1 mol %:0.26 mol %) by adjusting the composition of target materials.

Next, a HfₓZr₁₋ₓO₂ (HZO) (Hf/Zr=0.43:0.57) layer serving as a ferroelectric layer 54 was formed into a film having a thickness of 10 nm on the lower electrode 53 by an atomic layer deposition (ALD) method.

Next, the upper electrode 55 serving as the composite metal oxide electrode, that is, a layer of an In—Si—O-based oxide electrode containing In₂O₃ and SiO₂ at a ratio of 0.26 mol % of SiO₂ per 1 mol % of In₂O₃:(In₂O₃:SiO₂=1 mol %:0.26 mol %) was formed into a film having a thickness of 10 nm on the ferroelectric layer 54 by the same formation method as that of the lower electrode 53.

Next, rapid heating treatment was performed at 400° C. for 1 minute in the air.

Next, a laminated electrode of a Ti layer (thickness: 10 nm) and a Au layer (thickness: 100 nm) serving as a contact electrode 56 was formed on the upper electrode 55 by a resistance heating vapor deposition method.

Thus, the ferroelectric capacitor 50 was produced as the ferroelectric capacitor according to Example 13.

FIG. 9 shows measurement results of endurance characteristics (values each normalized with a dielectric breakdown rewrite frequency in a sample including only a contact electrode without including a composite metal oxide electrode) of the respective ferroelectric capacitors according to Examples 1, 2, 12 and 13 and Comparative Example 1.

As shown in FIG. 9, it is recognized that the normalized dielectric breakdown rewrite frequency is increased along with an increase in oxide dissociation energy of the oxide added to In₂O₃. This is consistent with the results shown in FIG. 6 regarding the rewritable frequency before normalization.

In addition, as shown in FIG. 9, when the In—Si—O-based oxide (ISO) was used as the composite metal oxide electrode, in the ferroelectric capacitor according to Example 2 in which the composite metal oxide electrode was applied to only the upper electrode 35 and the ferroelectric capacitor according to Example 12 in which the composite metal oxide electrode was applied to only the lower electrode 43, the results that the rewritable frequency was increased more in the ferroelectric capacitor according to Example 12 were obtained.

The cause for the foregoing is conceived as described below. In the ferroelectric capacitor according to Example 2 produced by performing rapid heating treatment at 400° C. for 1 minute after the formation of the upper electrode 35 (composite metal oxide electrode) and the ferroelectric capacitor according to Example 12 produced by performing rapid heating treatment at 400° C. for 1 minute before the formation of the upper electrode 45, the ferroelectric layer 34 and the ferroelectric layer 44 were influenced by different thermal expansions at the time of the rapid heating treatment due to the layers themselves and the surrounding layers, and the ferroelectric layer 44 in Example 12 obtained a more stable ferroelectric phase even with the same layer of HfₓZr₁₋ₓO₂ (HZO).

In addition, as shown in FIG. 9, in the ferroelectric capacitor 50 according to Example 13, the rewritable frequency is increased as compared to the ferroelectric capacitor 30 in which the composite metal oxide electrode was applied to only the upper electrode 35 according to Example 2 and the ferroelectric capacitor 40 in which the composite metal oxide electrode was applied to only the lower electrode 43 according to Example 12, and of the ferroelectric capacitors according to Examples 1 to 12, the most satisfactory ferroelectricity and endurance characteristic are obtained.

That is, it is conceived that, in the ferroelectric capacitor according to Example 13, both electrodes of the upper electrode 55 and the lower electrode 53 each include the composite metal oxide electrode, and hence the formation of defects such as oxygen vacancy and an unintended interface layer can be suppressed at two interfaces between the ferroelectric layer 54 and the upper electrode 55 and between the ferroelectric layer 54 and the lower electrode 53.

### REFERENCE SIGNS LIST

10, 20, 30, 40, 50 ferroelectric capacitor
12, 22, 32, 42, 52 lower contact electrode
13, 43, 53 lower electrode (composite metal oxide electrode)
14, 24, 34, 44, 54 ferroelectric layer
15, 25, 35, 55 upper electrode (composite metal oxide electrode)
16, 26, 36, 56 upper contact electrode
23, 33 lower electrode
31, 41, 51 substrate
45 upper electrode

1. A ferroelectric capacitor, comprising:
an upper electrode;
a lower electrode; and
a ferroelectric layer arranged between the upper electrode and the lower electrode so as to be in close contact therewith,
wherein at least one electrode selected from the group consisting of the upper electrode and the lower electrode includes a composite metal oxide electrode formed so as to contain a composite metal oxide in which a second oxide is added to a conductive first oxide containing at least one metal element selected from the group consisting of In, Ga, Zn, Sn, Ru, Ir and Sr at a molar ratio smaller than that of the first oxide, the second oxide having oxygen dissociation energy, when considered as a metal oxide of one of the metal elements, which is larger by 200 kJ/mol or more, as compared to the metal oxide having a largest oxygen dissociation energy among the first oxides.

2. The ferroelectric capacitor according to claim 1, wherein each of the upper electrode and the lower electrode includes the composite metal oxide electrode.

3. The ferroelectric capacitor according to claim 1, further comprising a contact electrode formed on a surface of a layer of the composite metal oxide electrode on an opposite side to a surface thereof in close contact with the ferroelectric layer.

4. The ferroelectric capacitor according to claim 1, wherein the composite metal oxide is formed by adding 0.02 part by mole to 0.5 part by mole of the second oxide to 1 part by mole of the first oxide.

5. The ferroelectric capacitor according to claim 1, wherein the composite metal oxide is formed by adding the second oxide containing at least one element selected from the group consisting of Zr, Ce, La, Si, Hf, Ta and C to the first oxide selected from the group consisting of a Sn—O-based oxide, an In—Sn—O-based oxide, a Ga—Sn—O-based oxide, a Zn—Sn—O-based oxide, an In—Ga—Sn—O-based oxide, an In—Zn—Sn—O-based oxide, a Ga—Zn—Sn—O-based oxide and an In—Ga—Zn—Sn—O-based oxide.

6. The ferroelectric capacitor according to claim 1, wherein the composite metal oxide is formed by adding the second oxide containing at least one element selected from the group consisting of Er, Dy, Ni, V, Ge, Ti, W, Nb, Zr, Ce, La, Si, Hf, Ta and C to the first oxide selected from the group consisting of an In—O-based oxide, a Ga—O-based oxide, a Zn—O-based oxide, an In—Ga—O-based oxide, an In—Zn—O-based oxide, a Ga—Zn—O-based oxide and an In—Ga—Zn—O-based oxide.

7. The ferroelectric capacitor according to claim 6, wherein the composite metal oxide is formed by adding the second oxide containing at least one element selected from the group consisting of Ti, W, Nb, Zr, La, Si, Hf, Ta and C to the In—O-based oxide.

8. The ferroelectric capacitor according to claim 7, wherein the composite metal oxide contains an oxide selected from the group consisting of an In—W—O-based oxide and an In—Si—O-based oxide.

9. The ferroelectric capacitor according to claim 1, wherein the composite metal oxide is formed by adding the second oxide containing at least one element selected from the group consisting of Zr, Ce, La, Si, Hf, Ta and C to the first oxide selected from the group consisting of a Ru—O-based oxide, an Ir—O-based oxide, a Sr—Ru—O-based oxide and an In—Sr—Ru—O-based oxide.

10. The ferroelectric capacitor according to claim 9, wherein the composite metal oxide contains an In—Sr—Ru—Si—O-based oxide.

11. The ferroelectric capacitor according to claim wherein the composite metal oxide electrode has a thickness of from 0.5 nm to 20 nm.

12. The ferroelectric capacitor according to claim 3, wherein the composite metal oxide electrode has a thickness of from 0.5 nm to 2 nm.
